(19) United States
(12) Patent Application Publication
(10) Pub. No.: US 2010/0193695 A1
(43) Pub. Date: Aug. 5, 2010

(54) CARBON MATERIAL DOSIMETER

(75) Inventors: John T.W. Yeow, Mississauga (CA); Jiazhi Ma, Waterloo (CA)

Correspondence Address: WPAT, PC;INTELLECTUAL PROPERTY ATTORNEYS, 2030 MAIN STREET, SUITE 1300, IRVINE, CA, 92614, US

(73) Assignee: John T.W. Yeow, Mississauga, ON (CA)

(21) Appl. No.: 12/667,852

(22) PCT Filed: Nov. 14, 2008
(86) PCT No.: PCT/CA08/02015

§ 371 Date: Apr. 22, 2010

(51) Int. Cl. G01T 1/02; G01T 1/24; H05K 13/00

(52) U.S. Cl. 250/370.07; 250/371; 29/592.1; 977/742; 977/773; 977/954

(57) ABSTRACT

Radiation dosimeters that are based on carbon materials such as carbon powder, carbon fibers, carbon nanoparticles and carbon nanotubes are developed. The dosimeter may contain a singular element or multiple sensing elements that are arrayed in 1-D, 2-D and 3-D formations. Each sensing element is made up of two electrodes with carbon materials deposited between the electrodes. The sensing elements may be deposited on flexible substrates to create flexible dosimeters. In addition, the carbon sensing materials may be deposited onto transparent substrates to achieve a transparent dosimeter. Transparent and/or flexible dosimeters can be fabricated with the carbon materials. The sensing elements are connected to external power sources. As the elements are exposed to radiation beams, the change in resistivity or conductance of the carbon materials is measured by current detection circuitry.

### BACKGROUND OF THE INVENTION

1. Field of the Invention

This invention relates to a detection device having carbon based sensing elements and a method of operation and construction thereof and, more particularly, to a dosimeter having carbon based sensing elements.

2. Description of the Prior Art

Dosimeters have been routinely used to calibrate and monitor the radiation treatment unit (e.g., linear accelerators for external beam therapy). Patient in vivo dosimeters are used during radiotherapy to monitor the dosage delivered to a patient in order to avoid unwanted exposure to the healthy tissue. Some commonly used dosimeters include ionization chambers, thermoluminescence dosimeters (TLDs), radiographic and radiochromic films, and semiconducting silicon diodes and metal-oxide-semiconductor field effect transistor (MOSFT) dosimeters. The large physical size of an ionization chamber limits its spatial resolution. In addition, ionization chambers require high bias voltage in order to achieve acceptable ionization collection efficiency. These drawbacks limit their applications for in vivo dose measurements.

The disadvantages of TLDs include: sensitivity to environmental conditions, handling procedures, and heating conditions. When TLDs are routinely used, their accuracy is low, and information is destroyed during the read-out process. Real-time measurements cannot be performed, and no information is given about the dose rate. Another main problem occurs when a TLD is initially exposed to a very high dose and later reused to measure a very low dose. One common disadvantage of film dosimeters is non-linear response to dose. In addition, both radiographic films and radiochromic films are not tissue equivalent. Another disadvantage of radiographic films is radiation energy dependence. The high atomic number of active material (silver bromide) leads to a distinct over-response to low-energy X-ray. For radiochromic films, they are self-developing. However it takes several hours for the colour change to stabilize sufficiently for evaluation. The variation of optical density with time is also temperature dependent and shows an increase in optical density. UV light may cause a colour change of radioachromic films without exposure to ionizing radiation. The disadvantages of MOSFET dosimeters include temperature dependency and limited life span. Radiation induced charges lead to a threshold voltage shift of the MOS transistor. However, the variation of temperature also causes a change of threshold voltage. Additional efforts need to be taken to eliminate temperature interference.

### SUMMARY OF THE INVENTION

It is an object of the present invention to provide a dosimeter having carbon based sensing elements for the detection of radiation beams. Said carbon-based elements need not be co-mixed with any further substance, such as a polymer, and are preferably, though need not be, semi-conducting.

A detection device for detecting radiation comprises at least one carbon based sensing element. Each sensing element has two electrodes thereon, the electrodes being connected to a power source. The at least one sensing element is accessible to radiation, with a current detector to detect current generated between the electrodes when radiation interacts with the at least one sensing element.

A method of detecting radiation uses a radiation detection device having at least one sensing element. The at least one sensing element has two electrodes thereon, the electrodes being connected to a power source. The at least one sensing element is accessible to radiation and has output wires. The method comprises placing the detection device in a path of a radiation beam, the radiation beam causing a current to flow between the electrodes, measuring the current flow at the output wires and determining a dosage level of the radiation beam.

A method of constructing a detection device to detect radiation, the detection device having at least one carbon based sensing element, the method comprising placing two electrodes on each sensing element, connecting the electrodes to a power source, connecting output wires to each of the sensing elements, and arranging a current detector to detect current flowing in the output wires.

A method of detecting radiation uses a dosimeter having at least one sensing element. The at least one sensing element has two electrodes thereon, the electrodes being connected to a power source. The at least one sensing element is accessible to radiation and has output wires. The method comprises placing the dosimeter in a path of a radiation beam, the radiation beam causing current to flow between the electrodes, measuring the current flow at the output wires and determining a dosage level of the radiation beam.

### BRIEF DESCRIPTION OF THE DRAWINGS

FIG. 1A is a schematic perspective view of a sensing element based on a carbon fiber sheet;

FIG. 1B is a schematic side view of the sensing element in FIG. 1A;

FIG. 2A is a schematic perspective view of a sensing element based on a film;

FIG. 2B is a schematic side view of the sensing element in FIG. 2A;

FIG. 2C is a schematic top view of the sensing element in FIG. 2A;

FIG. 3A is a schematic perspective view of a dosimeter having multiple sensing elements;

FIG. 3B is a schematic top view of the dosimeter in FIG. 3A;

FIG. 4A is a schematic top view of a further embodiment of a dosimeter having multiple sensing elements;

FIG. 4B is a schematic top view of the dosimeter in FIG. 4A;

FIG. 4C is a schematic side view of the dosimeter in FIG. 4A;

FIG. 5A is a schematic side view of a dosimeter having a housing with a control circuit on a same side as sensing elements;

FIG. 5B is a schematic side view of a dosimeter with a housing and a control circuit on an opposite side from the sensing elements;

FIG. 6A is a schematic perspective view of a transparent sensing element;

FIG. 6B is a schematic side view of the transparent sensing element in FIG. 6A;

FIG. 7A is a schematic top view with flexible sensing element;

FIG. 7B is a schematic perspective view of the flexible sensing element in FIG. 7A;

FIG. 8A is a schematic side view showing the use of a transparent and flexible dosimeter;

FIG. 8B is a schematic end view showing the use of the dosimeter in FIG. 8A;

FIG. 9A shows the use of a dosimeter on a person who is exposed to radiation; and

FIG. 9B shows the use of a dosimeter formed into the shape of a glove.

FIG. 10 is an illustration of the experimental setup for testing the present invention.

FIG. 10A is a graphic illustration of current passing through carbon nanotube film of a carbon nanotube film-based dosimeter as a function of dose rate using photon beams.

FIG. 10B is a graphic illustration of current passing through carbon nanotube film of a carbon nanotube film-based dosimeter as a function of dose rate using electron beams.

FIG. 10C is a graphic illustration of current passing through carbon fibre sheet of a carbon fibre sheet-based dosimeter with field sizes of 1×1 cm² and 1.8×1.8 cm² as a function of dose rate using photon beams.

FIG. 10D is a graphic illustration of current passing through the carbon fibre sheet of a carbon fibre sheet-based dosimeter as a function of monitor unit using photon beams.

FIG. 10E is a graphic illustration of current passing through the carbon fibre sheet of a carbon fibre sheet-based dosimeter as a function of field size using photon beams.

FIG. 10F is a graphic illustration of current passing through the carbon nanotube film of a carbon nanotube film-based dosimeter as a function of field size using photon beams.

FIG. 10G is a graphic illustration of current passing through carbon nanotube film of a carbon nanotube-based film dosimeter as a function film density using a 6 MV photon beam.

FIG. 10H is a graphic illustration of current passing through the carbon nanotube film of a carbon nanotube film-based dosimeter as a function of electron beam energy.

FIG. 10I is a graphic illustration of current passing through a flexible carbon nanotube of a carbon nanotube-based flexible dosimeter in a flat and curved configuration.

FIG. 10J is a graphic illustration of current passing through a carbon nanotube-based array as a function of time using photon beams intermittently turned ON and OFF.

FIG. 10K is a graphic illustration of current through a carbon nanotube-based array as a function of time using electron beams intermittently turned ON and OFF.

### DETAILED DESCRIPTION OF A PREFERRED EMBODIMENT

The dosimeter comprises one or more individual carbon material-based sensing elements. Each sensing element can operate independently as a radiation sensor. The sensing element is based on one of a variety of carbon-based materials which can be semi-conducting or not, including, but not limited to carbon fiber sheets, carbon fiber films, carbon sheets, carbon nanoparticles, carbon films or a carbon nanotube film. One advantage of the present invention is that the carbon materials used to fabricate the sensing element may be used raw and need not be intermixed with another substance such as a polymer. In this way, the sensing element of the present invention is much less expensive to fabricate than other sensors which comprise a composite material.

There are many methods to manufacture the carbon dosimeters. The fabrication methods of the dosimeter are described more particularly as follows: (i) When a carbon fiber sheet is used as the sensing material, the sheet is sandwiched between two plastic holders. Each holder has an opening to allow radiation to interact with the carbon fiber sheet directly. Electrodes are made on the lower holder to make electrical contacts with the carbon fiber sheet; (ii) When a carbon fiber film or a carbon nanotube film is used as a sensing material, the carbon fiber film or carbon nanotube film is spin coated on a transparent and flexible substrate, which has electrodes prepared on the top in advance; and (iii) Carbon particles and materials may also be spray-coated onto transparent and flexible substrate. In all cases, output wirings are connected to the electrodes to measure the change in resistivity or conductivity of the sensing material. Current detection circuitry measures the ionization current signal of each sensing element. The signals are subsequently multiplexed and acquired by the input channels of a data acquisition (DAQ) card. The collective signals from the sensing elements provide a 2D flatness profile of the radiation beam.

The dosimeter generates current responses according to the dose rate of incident radiation beams. And the dose information of the beams is provided by calculating the charge changes from the current responses and the delivery time of the radiation beams.

When ionizing radiation interacts with the sensing material in a sensing element, the high-energy particles (photons from X-ray beams or electrons from electron beams) transfer energy to the carbon atoms inducing electron and positive ion pairs. When a voltage applied between two electrodes of the sensing element, electrons and positive ions move to the cathode and anode, respectively, under the external electric field. This, in turn, creates a small ionizing current. The radiation dosage can be quantified from this current.

The advantages of carbon material dosimeters can be summarized as follows: i) the thickness of the sensing element is much smaller than its planar geometry; consequently, the dosimeter can be regarded as an on-planar radiation sensor and offers good spatial resolution; ii) the transparency and flexibility of the dosimeter enable the dosimeter to be placed on the treatment surface of patients for in-vivo dose measurements; iii) The atomic number of carbon material is 6, which could be regarded as tissue equivalent; therefore, carbon material dosimeters display linear responses to radiation dose. Moreover, in addition to dose measurements, dose rate information is also provided in the same time; iv) the carbon sensing material is economical and readily available. Moreover, the fabrication process itself is simple. Therefore, no expensive fabrication equipment and clean room environment are required.

In summary, a carbon material dosimeter has a high spatial resolution and offers a 2D map of radiation beam profile. Transparency and flexibility are the most attractive features of carbon material dosimeters, which make wearable dosimeter network possible and provide real-time dose monitoring in in-vivo measurements.

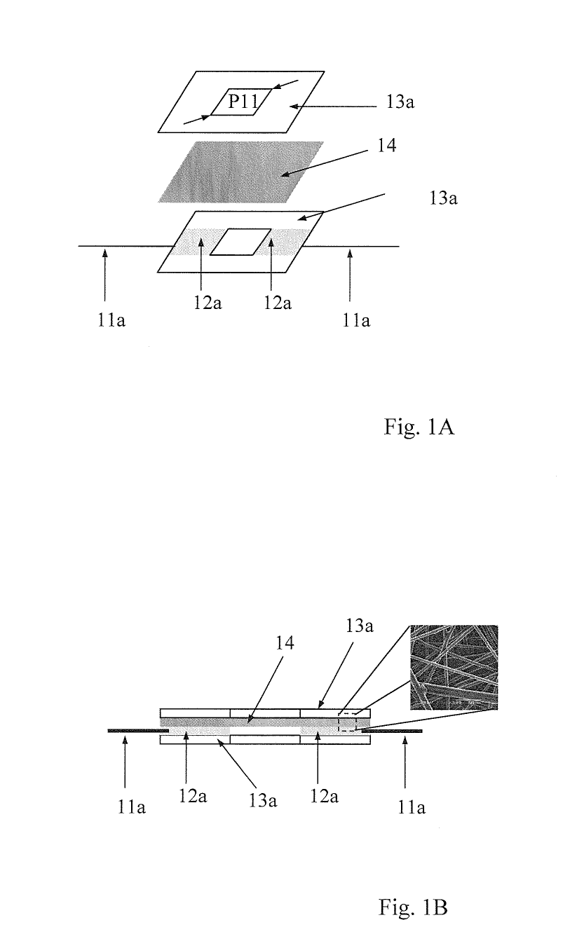

FIG. 1A is a schematic 3D view of a preferred carbon fiber sheet-based sensing element. The carbon fiber sheet 14 is used as sensing material. A sheet 14 is sandwiched between two parallel holders 13a. The parallel holders 13a are plastic material, such as Polymethylmethacrylate (PMMA). Each holder has a hole P11 to allow radiation interacting with the carbon fiber sheet 14 directly. The size of the hole P11 in the holder 13a determines the sensing area of each sensing element. Under certain embodiment and requirement, the shape of the hold can simply be square, circular, or any form factor. Metal electrodes 12a are made on the lower holder 13a to make electrical contacts with the carbon fiber sheet 14.

The shapes of the holder, the carbon fiber sheet, and the electrodes can simply be square, circular, or any form factor. The sizes of the holder, the carbon fiber sheet, and the electrodes can be varied under certain embodiments.

FIG. 1B is a schematic side view of a preferred carbon fiber sheet-based sensing element. As shown in the figure, each response output wiring 11a is connected to a metal electrode 12a. The length of the wirings is properly tailored to output the responses from the sensing element without generating unnecessary interference or noise.

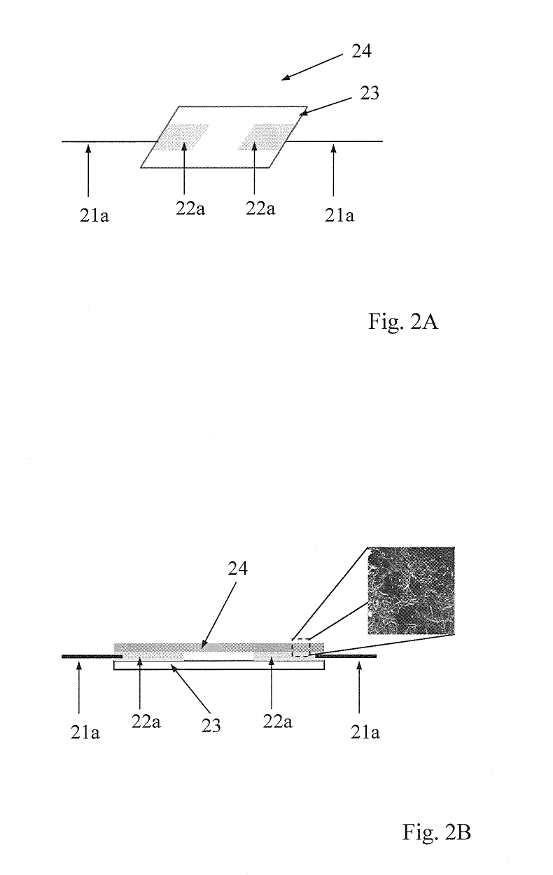

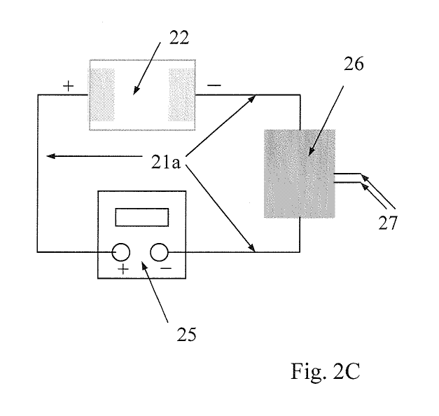

FIG. 2A is a schematic 3D view of a preferred carbon fiber film-based or carbon nanotube film-based sensing element. The sensing element includes a substrate 23, metal electrodes 22a, a carbon fiber film or a carbon nanotube film 24, and responses output wirings 21a.

The substrate 23 is transparent and flexible. The metal electrodes 21a are made on top of the substrate 23 before spin coating a carbon fiber film or a carbon nanotube film 24. The thickness and density of the carbon fiber film or carbon nanotube film are varied under certain embodiments. The shapes of the carbon fiber film or carbon nanotube film, electrodes, and the substrate can simply be square, circular, or any form factor. The sizes of the carbon fiber film or carbon nanotube film, electrodes, and the substrate can be varied under certain embodiments.

FIG. 2B is a schematic side view of a preferred carbon fiber film-based or carbon nanotube film-based sensing element. As shown in the figure, each response output wiring 21a is connected to a metal electrode 22a. The length of the wirings is properly tailored to output the responses from the sensing element without generating unnecessary interference or noise.

Response output wirings 11a and 21a are made of conductive material and connected to the input of a control circuit 33.

FIG. 2C is a top view of a sensing element (either based on carbon sheet or based on carbon film) connected to a power source and a control circuit. The sensing element 22, power source 25, and control circuit 26 are connected in serial through output wirings 21a. The control circuit 26 can detect and record current responses and output the responses through dosimeter output wirings 27.

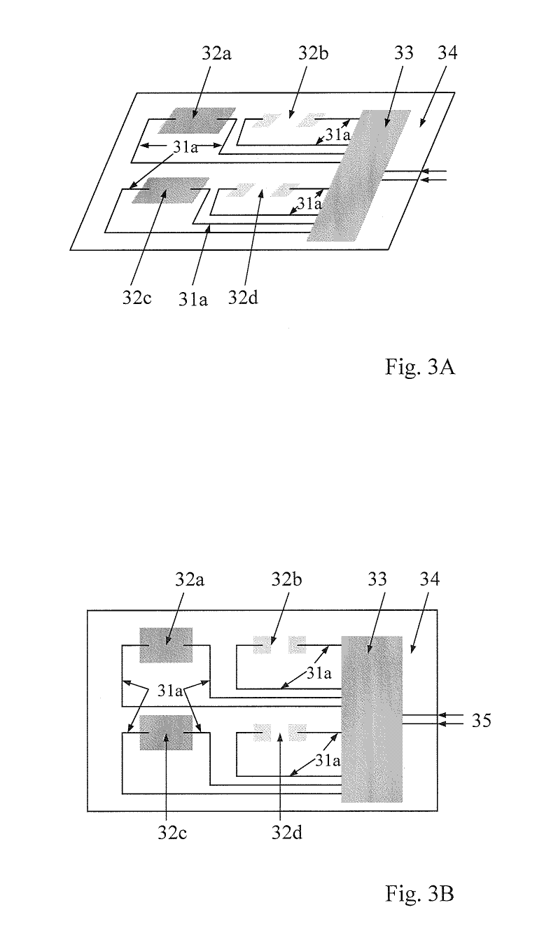

FIG. 3A is a schematic 3D view of a preferred dosimeter comprised of multiple sensing elements. A dosimeter includes multiple sensing elements 32a-d, element responses output wirings 31a, a control circuit 33, a substrate 34, and dosimeter output wirings 35.

The number of and size of sensing elements may vary depending on certain embodiments and application requirements. It is possible that on the same substrate, sensors of different sizes could be fabricated. It is envisioned that certain locations will require higher spatial resolution sensing and, therefore, an increased number of sensing elements each having relatively smaller sizes. Likewise certain locations will not require as high a degree of spatial resolution sensing and, therefore, will require fewer sensing elements. Similarly, the layouts and positions of sensing elements and the control circuit can be varied under certain embodiments as well. In certain applications it may be desirable to have a three-dimensional array (i.e. n×n×n) of such sensors, so that the trajectory of the radiation particles can also be detected.

A control circuit 33 can process responses from multiple sensing elements. The circuit is programmed to record each sensing element one by one at each time consequently and repeatedly. The current responses recorded by the circuit can be processed and output through dosimeter output wirings 35.

A substrate 34 is a transparent and flexible material to hold the sensing elements, the control circuit, and the wirings.

Dosimeter output wirings 35 are made of conductive material. The layout and lengths of the output wirings are under certain embodiments and application requirements.

FIG. 3B is a schematic top view of a preferred dosimeter comprised of multiple sensing elements. As shown in the figure, the dosimeter includes 4 sensing elements 32a-d. The number of sensing elements can be varied under certain application requirements.

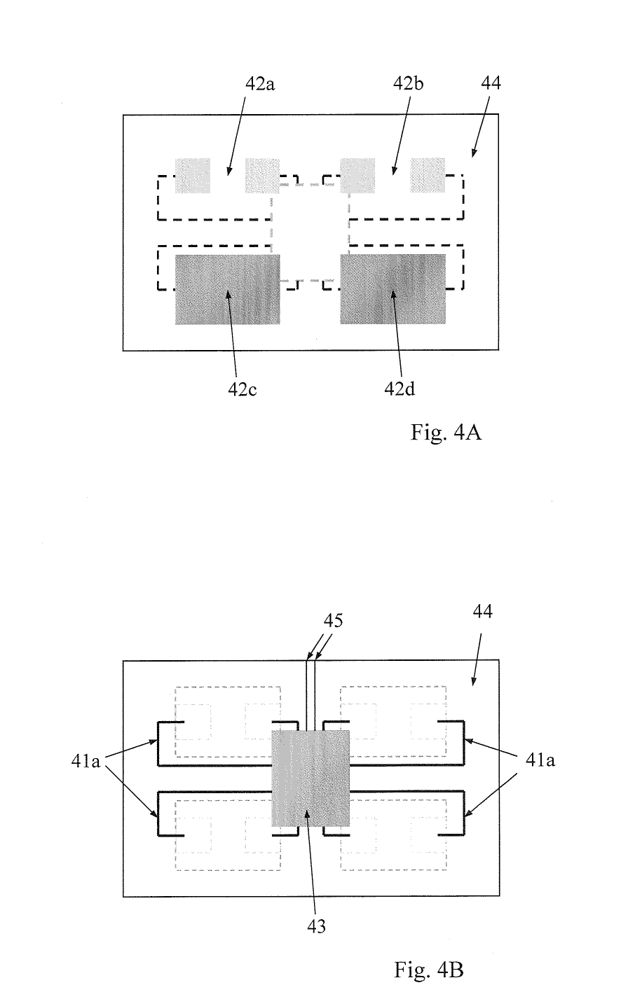

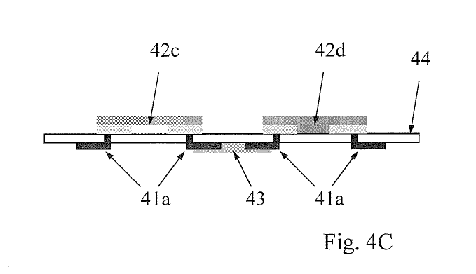

FIG. 4A is a schematic top view of a preferred dosimeter comprised of multiple sensing elements with a control circuit on the back of the substrate. FIG. 4B is a schematic bottom view of a preferred dosimeter comprised of multiple sensing elements with a control circuit on the back of the substrate. The dosimeter includes multiple sensing elements 42a-d on the top of a substrate 44 and element responses output wirings 41a, a control circuit 43, and dosimeter output wirings 45 on the back of back of the substrate 44.

The number of sensing elements is depending on certain embodiments and can be varied under certain application requirements application requirements. The layouts and positions of sensing elements and the control circuit can be varied under certain embodiments as well.

A control circuit 43 can process responses from multiple sensing elements. The circuit is programmed to record each sensing element one by one at each time consequently and repeatedly. The current responses recorded by the circuit can be processed and output through dosimeter output wirings 45. A substrate 44 is a transparent and flexible material to hold the sensing elements, the control circuit, and the wirings. Dosimeter output wirings 45 are made of conductive material. The layout and lengths of the output wirings are under certain embodiments and application requirements.

FIG. 4C is a schematic side view of a preferred dosimeter comprised of multiple sensing elements with a control circuit on the back of the substrate. As shown in the figure, sensing elements are on the top of the substrate (Two sensing elements 42c and 42d are shown in this figure. Sensing elements 42a and 42b are blocked and cannot be seen from this point of view). Element responses output wirings 41a and the control circuit 43 are on the bottom of the substrate. Dosimeter output wirings 45 are also on the bottom of the substrate, which is blocked by the control circuit and cannot be seen at this point of view. The electrodes of the sensing elements and element responses wirings are connected via vias.

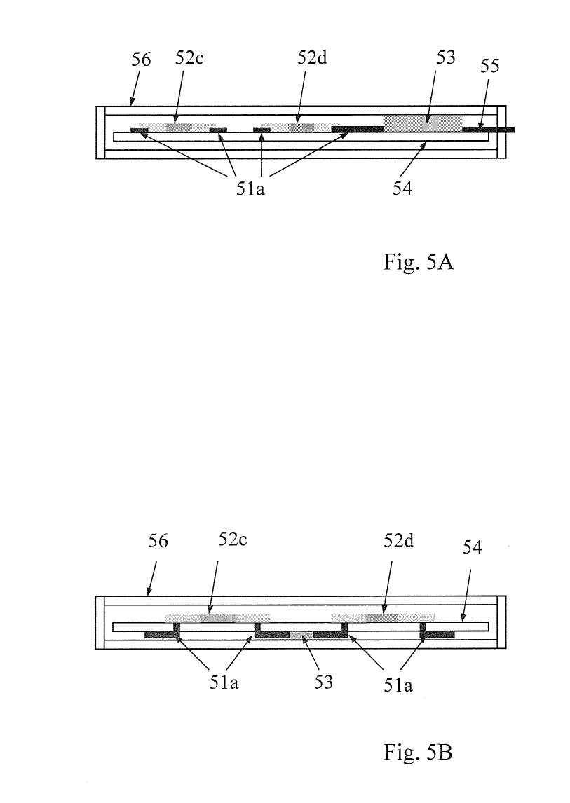

FIG. 5A is a side view of a preferred dosimeter comprised of multiple sensing elements with housing—control circuit on the same side. Response output wirings 51a, multiple sensing elements 52a-d, a control circuit 53, and dosimeter output wirings 55 are on the top of a substrate 54. Dosimeter housing (without openings) 56 packages the above mentioned components together. The material of dosimeter housing 56 is transparent and flexible, such as plastics.

FIG. 5B is a side view of a preferred dosimeter comprised of multiple sensing elements with housing—control circuit on the back of the substrate. Multiple sensing elements 52a-d are on the top of a substrate 54 and element responses output wirings 51a, a control circuit 53, and dosimeter output wirings 55 are on the back of a substrate 54. Dosimeter housing (without openings) 56 packages the above mentioned components together. The material of dosimeter housing 56 is transparent and flexible, such as plastics.

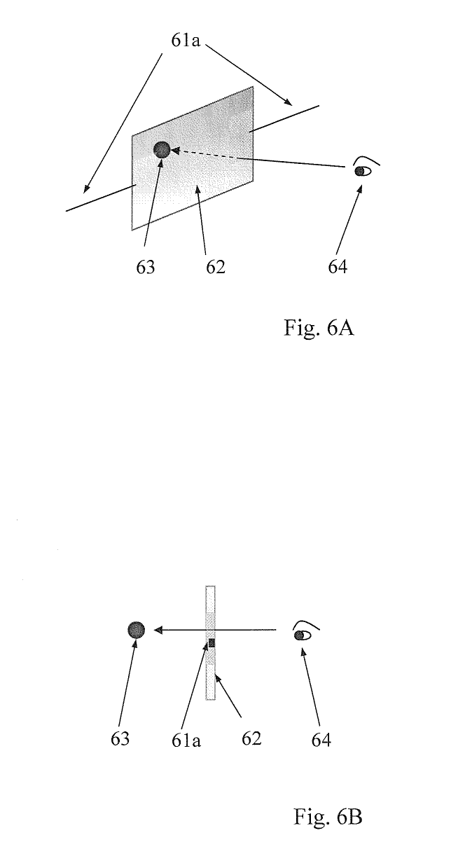

FIG. 6A is a 3D view of a transparent sensing element (either based on carbon sheet or carbon film). FIG. 6B is a side view of a transparent sensing element. An object 63 and an observer 64 are in the opposite sides of a transparent sensing element 62. The observer 64 is able to see the object 63 through the sensing element 62.

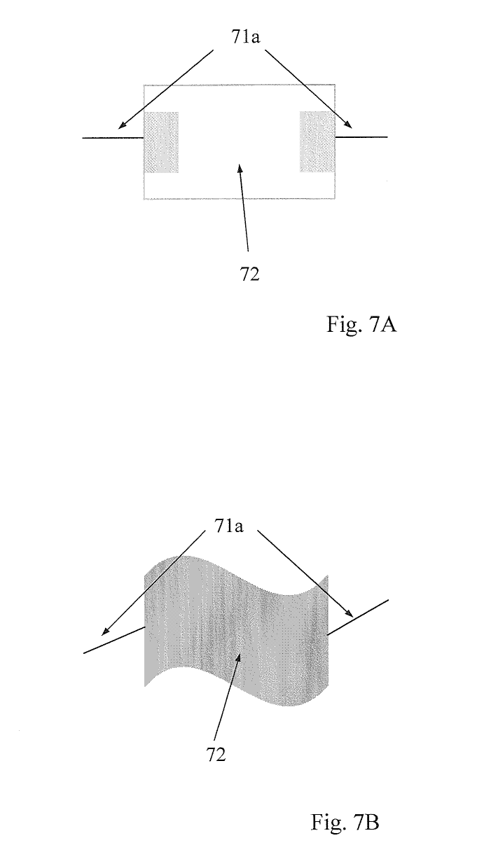

FIG. 7A is a top view of a flexible sensing element (either based on carbon sheet or carbon film) before bending. FIG. 7B is a 3D view of a flexible sensing element after bending.

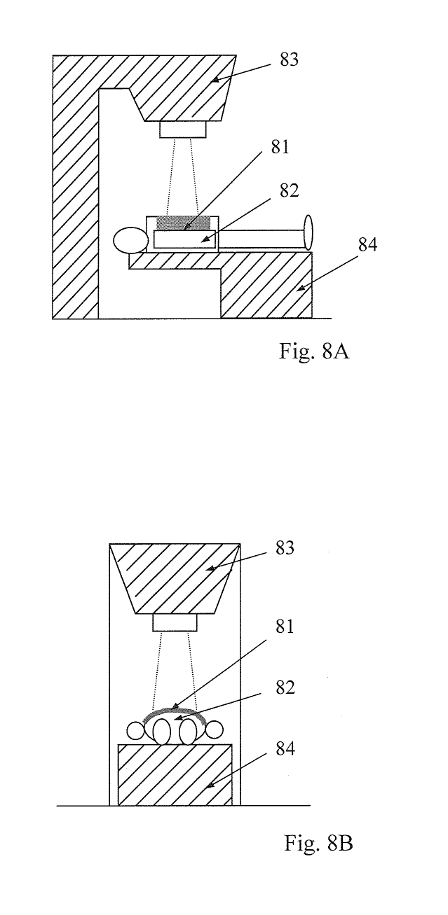

FIG. 8A is a side view of an application of a transparent and flexible dosimeter. The flexible dosimeter 81 is put on the top of an irradiated object 82, which can be a part of human body. The dosimeter can conform to the contour of the object. The irradiated object 82 and the flexible dosimeter 81 are placed on the top of a treatment couch 84 underneath a linear accelerator head 83.

FIG. 8B is an axial side view of an application of a transparent and flexible dosimeter. The flexible dosimeter 81 is bent to conform to the contour of the irradiated object 82. There is no difference between using carbon materials for the detection of electron and photon beams. There is no different set-up required of dosimeter to detect electron and photon beams.

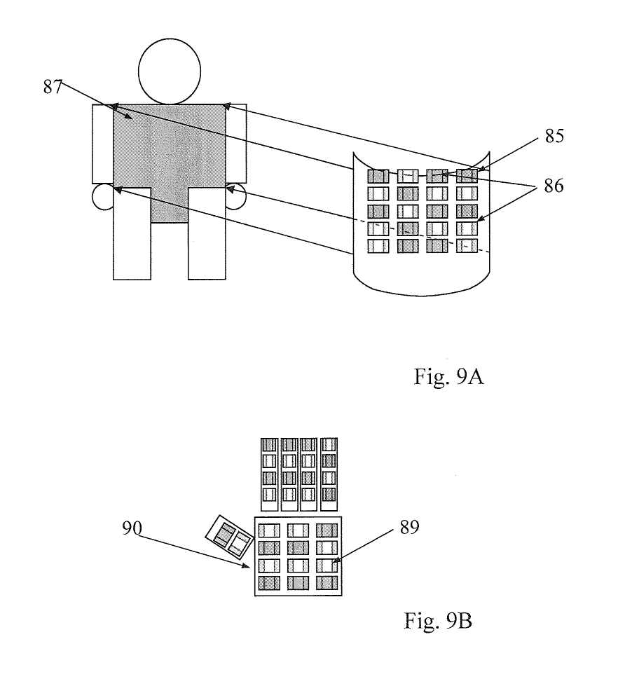

In addition to applications in the medical industry, the transparent and flexible dosimeter can be applied to any situations where radiation detection is important. For example, the dosimeter can be used for the detection of radiation exposure on an aircraft or in the nuclear industry. FIG. 9A shows the method of using the dosimeter 85 on a person who is exposed to radiation. The radiation sensing elements 86, which can be either transparent or flexible or both, can conform to the contour of the irradiated 87. FIG. 9B shows the dosimeter 89 can be made into the shape of a glove 90 that is used to handle radioactive materials. Similarly, a container or a window could incorporate the transparent and flexible dosimeter for detection of a radiation exposure without impeding the ability for visual inspection.

The carbon fiber sheet, carbon sheet, carbon nanodots and carbon nanotube/carbon nanotube powder are commercially available. For carbon fiber films, carbon films and carbon nanotube films, these can be fabricated by mixing carbon fiber powder, carbon powder or carbon nanotube powder, respectively, in a solution to form a suspension. The suspension is then ultrasonicated and spin coated or sprayed onto a substrate to form a thin film. The substrate can be transparent and/or flexible. For example, polymethylmethacrylate (PMMA), or plastic materials. The substrate is heated and the spin coating or spraying and heating is repeated, if necessary, in order to achieve the desired film thickness.

The materials of electrodes can be gold, copper, or other conductive metals. The methods to construct electrodes include:

1. Evaporate, sputter, or stick electrodes on holder, and then sandwich the carbon fiber sheet or carbon sheet between two holders;

2. Evaporate, sputter, or stick electrodes on carbon fiber sheets or carbon sheets, then sandwich the sheets between two holders without electrodes;

3. Evaporate, sputter, or stick electrodes on substrates in advance before forming the carbon fiber films, carbon films, or carbon nanotube films;

4. Evaporate, sputter, or stick electrodes on the carbon fiber films, carbon films, or carbon nanotube films after forming the films on the substrate without electrodes.

### EXPERIMENTAL RESULTS

The present invention is further illustrated and described by the following experimental results.

Experimental Setup

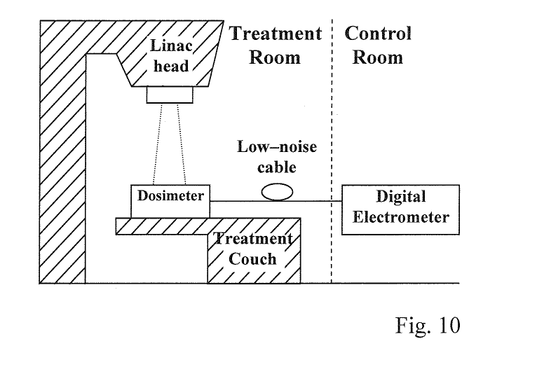

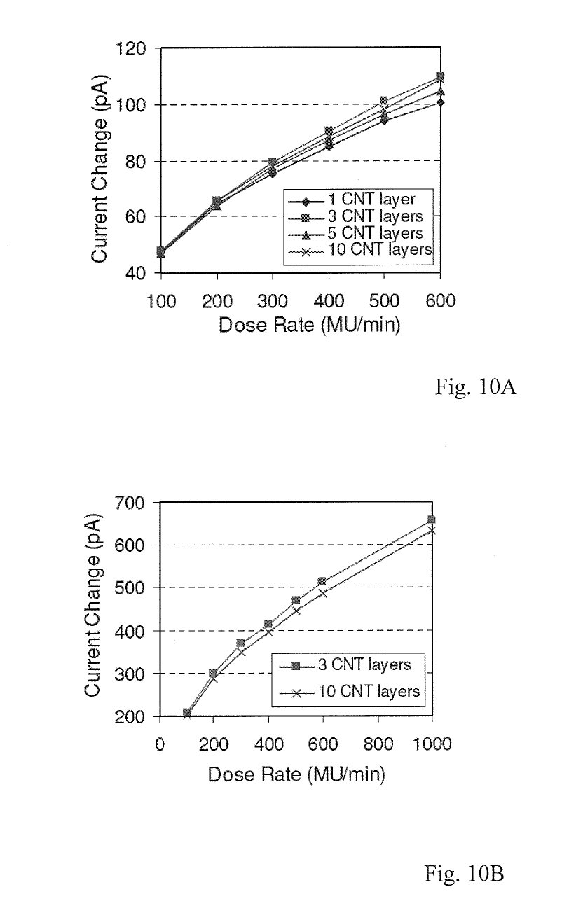

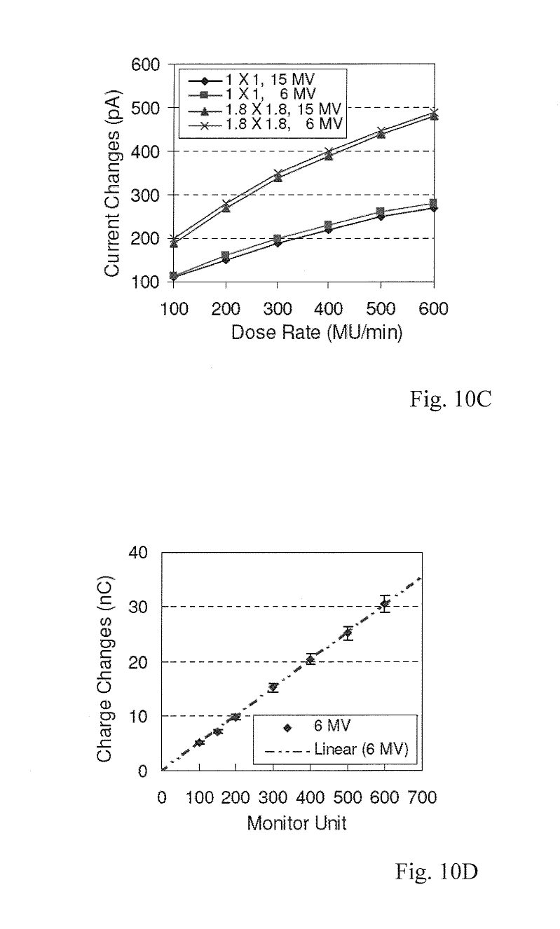

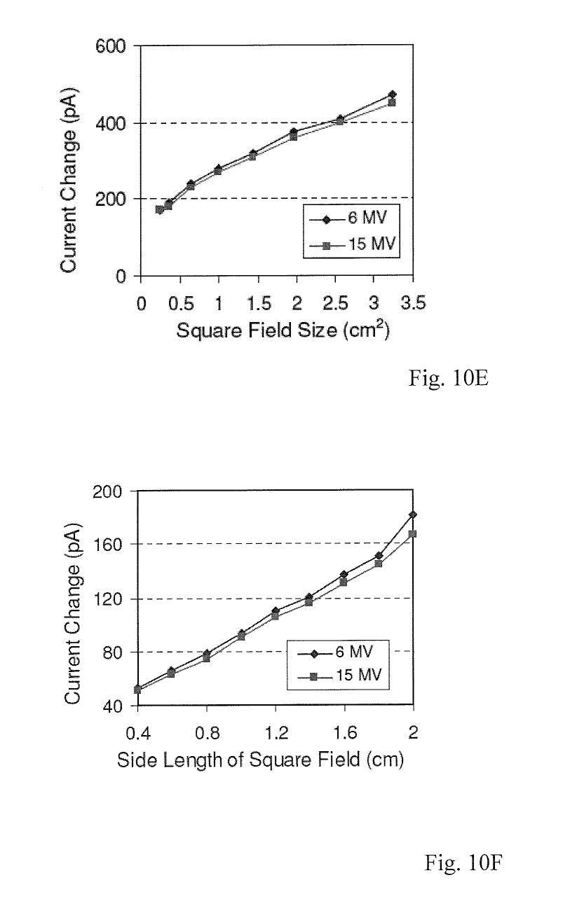

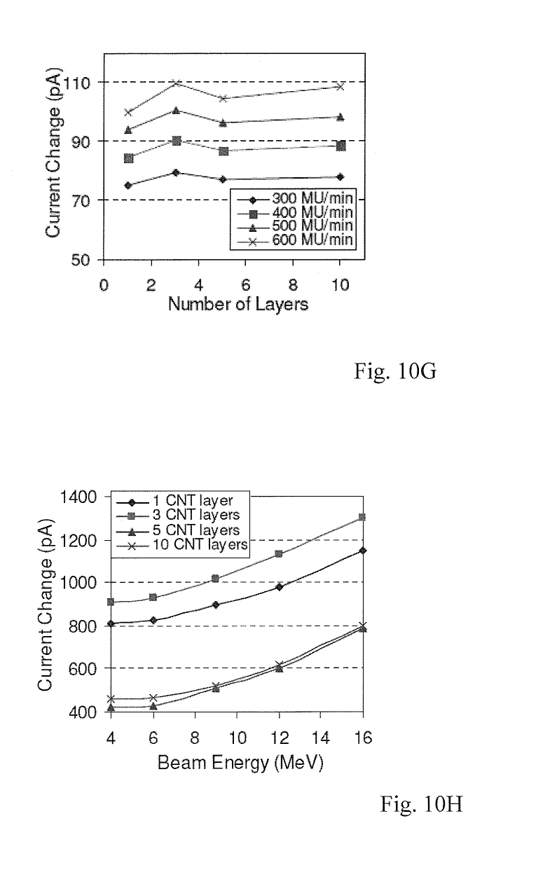

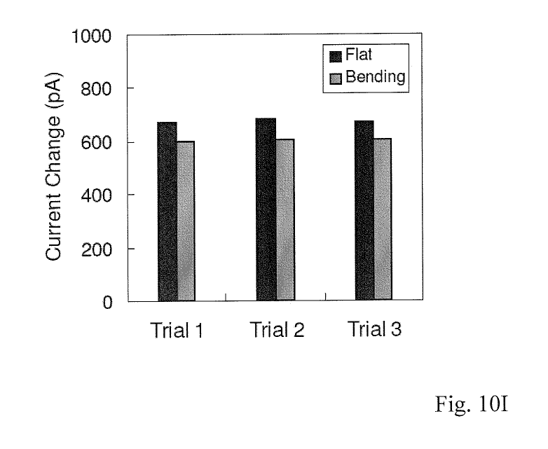

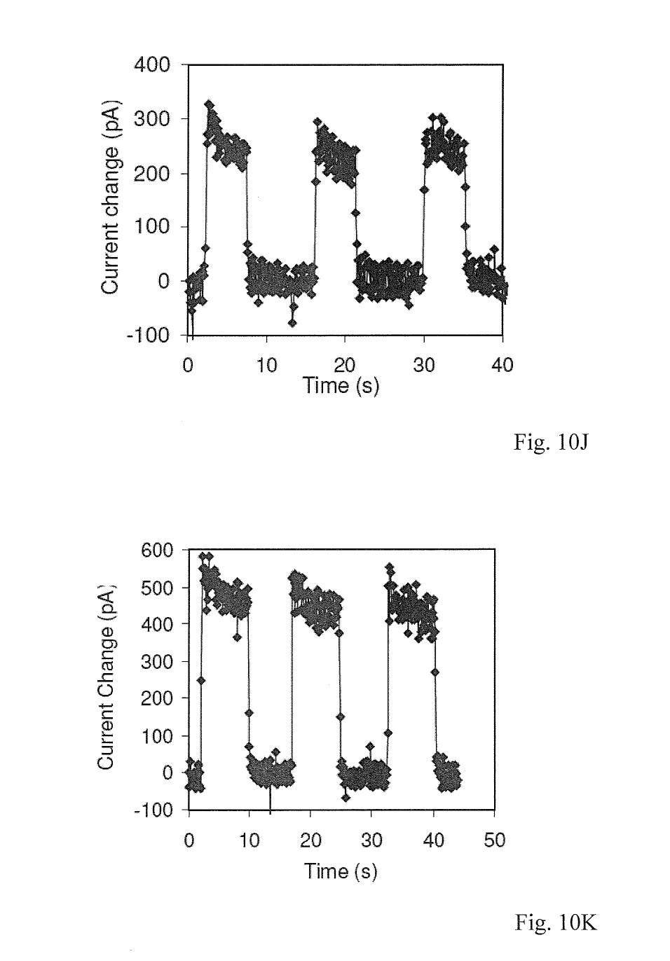

A carbon fibre sheet-based dosimeter, a carbon nanotube-based film dosimeter, a carbon nanotube-based flexible dosimeter and a carbon nanotube array have been tested with photon and electron beams produced by a medical linear accelerator to measure dose, dose rate, field size and film density. The dosimeter was placed under the accelerator head with source to surface distance of 100 cm. Signals were measured by a digital electrometer. Low noise cable was used to connect the dosimeter to the electrometer in order to eliminate background noise interference. Bias voltage was also provided by the electrometer. A schematic drawing of the experimental setup is shown in FIG. 10.

The carbon nanotube-based dosimeters used in the experiments described herein were single-walled nanotubes purified to remove large catalyst particles. The carbon nanotubes used had an average diameter of 2 nanometers and an average length of 2 micrometers. Various layers of carbon nanotube films, ranging from one to ten layers, were fabricated. One layer of carbon nanotube film consists of 0.0016 mg of carbon nanotubes.

The carbon fibre sheets used in the experiments described herein consisted of carbon fibres having diameters between 5 and 10 micometers. The thickness of each sheet is approximately 150 micometers.

The specifications of the carbon nanotubes and carbon fibre sheets used in the experiments are illustrative and not restrictive of the carbon nanotubes and carbon fibre sheets or any other carbon-based sensing material described herein which may be used in accordance with the present invention. Other specifications may be used while still remaining within the scope of invention.

Dose Rate Measurement

In dose rate measurement, the dose rate was set to be 100, 200, 300, 400, 500, and 600 MU/min for photon beams and 100, 200, 300, 400, 500, 600, and 1000 MU/min for electron beams. Current changes were measured by the electrometer. FIGS. 10A and 10B graphically illustrate the current change passing through the carbon nanotube film as a function of dose rate for 6 MV photon beams and 4 MeV electron beams, respectively. It is seen that the current change passing through the carbon nanotube films increases with an increase in the dose rate for both 6 MV photon beams and 4 MeV electron beams.

FIG. 10C graphically illustrates the current change passing through the carbon fibre sheet of a carbon fibre sheet-based dosimeter for both 6 and 15 MV photon beams with field sizes of 1×1 cm² and 1.8×1.8 cm². Likewise, it is seen that the current change passing through the carbon fibre sheet increases with an increase in dose rate for both 6 MV and 15 MV photon beams.

Dose Measurement

In dose measurement, photon beams were used to deliver 100, 150, 200, 300, 400, 500, and 600 MU radiation dosages to a carbon fibre sheet-based dosimeter. Charge changes were measured by the electrometer. FIG. 10D graphically illustrates the current changes passing through the carbon fibre sheet as a function of monitor unit for a 6 MV photon beam. It is seen that the current change passing through the carbon nanotube film increases in relation to monitor unit for a 6 MV photon beam.

Field Size Measurement

In field size measurement, the size of a square field was changed from 0.5×0.5 cm² to 1.8×1.8 cm² for 6 MV and 15 MV photon beams. Current changes were measured by the electrometer. FIG. 10E graphically illustrates the current change passing through the carbon fibre sheet of a carbon fibre sheet-based dosimeter as a function of the side length of a square field. FIG. 10F graphically illustrates the current change passing through the carbon nanotube film of a carbon nanotube-based film dosimeter as a function of the side length of a square field. It can be seen that the current change passing through the carbon fibre sheet and carbon nanotube film, respectively, increases with an increase in the field size of photon beams for 6 and 15 MV photon beams.

Carbon Nanotube Film Density Measurement

In CNT film density measurement, dosimeters with different CNT densities were irradiated by the photon beams. Current changes were measured by the electrometer. FIG. 10G graphically illustrates the current change passing through the carbon nanotube film as a function of the number of layers of CNTs on the top of the substrate for a 6 MV photon beam.

Carbon Nanotube Film Beam Energy Measurement

In beam energy measurement, dosimeters were irradiated by electron beams with nominal energies at 4, 6, 9, 12, and 16 MeV. Current changes were measured by the electrometer. FIG. 10H graphically illustrates the responses of a CNT-based film dosimeter to electron beams with nominal energies at 4, 6, 9, 12 and 16 MeV.

Carbon Nanotube Flexible Testing

For a carbon nanotube-based flexible dosimeter, flexible testing was carried out by taking measurements both when the dosimeter was flat and when it was in a bent configuration using 4 MeV electron beams. After the dosimeter was irradiated at flat status, it was bent and irradiated under the same experimental conditions. The testing was repeated three times. Current changes were measured by the electrometer. FIG. 10I graphically illustrates the dosimeter responses on a flat and a curved or bent surface.

Carbon Nanotube Array Repeatability Measurement

Repeatability measurements were performed on a carbon nanotube-based array dosimeter utilizing both 15 MV photon beams and 6 MeV electron beams. Radiation beams were turned ON and OFF three times for each type of beam. Current changes were measured by the electrometer. FIG. 10J graphically represents the current change passing through the carbon nanotube array as a function of time where a 15 MV photon beam was intermittently turned ON and OFF. FIG. 10K graphically represents the current change passing through the carbon nanotube array as a function of time where a 6 MeV electron beam was intermittently turned ON and OFF.

The invention may be embodied in other specific forms without departing from the spirit or essential characteristics. The present embodiments are there to be considered in respects as illustrative and not restrictive, the scope of the invention being indicated by the appended claims rather than by the foregoing description, and all changes which come within the meaning and range of the equivalency of the claims are therefore intended to be embraced therein.

We claim:

1. A detection device for detecting radiation comprising at least one carbon-based sensing element, having a first electrode and a second electrode thereon, and a power source, wherein said at least one carbon-based sensing element comprises carbon materials; said first electrode and second electrode are connected to said a power source; said at least one carbon-based sensing element is accessible to radiation, with a current detector to detect current generated between aid electrodes when said radiation interacts with said at least one carbon-based sensing element.

2. A detection device as claimed in claim 1 wherein said at least one carbon-based sensing element is located on a substrate

3. A detection device as claimed in claim 2 wherein said current detector is mounted on an opposite side of said substrate from said at least one carbon-based sensing element.

4. A detection device as claimed in claim 1 wherein said carbon materials are formed in one or more of a carbon fiber sheet, a carbon fiber film, a carbon sheet, a carbon film, carbon nanoparticles or a carbon nanotube film.

5. A detection device as claimed in claim 1 wherein there are a plurality of carbon-based sensing elements.

6. A detection device as claimed in claim 5 wherein said plurality of carbon-based sensing elements are placed in a two-dimensional array.

7. A detection device as claimed in claim 5, wherein said plurality of carbon-based sensing elements are placed in an n-by-n array.

8. A detection device as claimed in claim 5 wherein said plurality of carbon-based sensing elements are placed in a three-dimensional array.

9. A detection device as claimed in claim 5 wherein each of said carbon-based sensing elements is connected to operate independently as a radiation sensor.

10. A detection device as claimed in claim 1 wherein said at least one carbon-based sensing element comprises a carbon fiber sheet used as sensing material, said carbon fiber sheet being sandwiched between a top plastic holder and a bottom plastic holder, each holder having a hole to allow radiation to interact with said sheet directly.

11. A detection device as claimed in claim 10 wherein said first electrode and second electrode are mounted on the bottom plastic holder and make electrical contact with said carbon fiber sheet.

12. A detection device as claimed in claim 1 wherein said carbon-based sensing element comprises one of a carbon fiber film and a carbon nanotube film used as sensing material, wherein said film is spin-coated, spray-coated or immersed on a substrate.

13. A detection device as claimed in claim 12 wherein said substrate is flexible, transparent, or flexible and transparent.

14. A detection device as claimed in claim 12 wherein said at least one carbon-based sensing element has a sensing material whereby carbon particles and materials are spray-coated onto said substrate.

15. A detection device as claimed in claim 1 wherein said first electrode and second electrode have output wirings to enable a change in resistivity or conductivity of the sensing material to be measured.

16. A detection device as claimed in claim 1 wherein said current detector is a control circuit connected to output wirings from said electrodes, said control circuit measuring an ionization current signal of each of said carbon-based sensing elements.

17. A detection device as claimed in claim 16 wherein there is a multiplexer located to multiplex said signals and a data acquisition card having input channels to acquire said signals.

18. A detection device as claimed in claim 17 wherein said device is a dosimeter and current is generated in accordance with a dose rate of incident radiation beams, a dose information of said beams being provided by calculating charge changes from current responses and delivery time of said radiation beams.

19. A detection device as claimed in claim 2 wherein said device is a dosimeter and said radiation is one of x-ray beams, electron beams and photon beams.

20. A dosimeter for detecting radiation having at least one carbon-based sensing element, having a first electrode and a second electrode thereon, and a power source; wherein said at least one carbon-based sensing element comprises carbon materials, said first electrode and second electrode are connected to a power source, said at least one carbon-based sensing element is accessible to radiation with a detector to detect current generated between the electrodes when said radiation contacts said at least one carbon-based sensing element.

21. A method of detecting radiation using a radiation detection device having at least one carbon-based sensing element, having a first electrode and a second electrode thereon, and a lower source; wherein said at least one carbon-based sensing element comprises carbon materials, said first electrode and second electrode are connected to a power source, said at least one carbon-based sensing element is accessible to radiation and has output wires, said method comprising placing said detection device in a path of a radiation beam, said radiation beam causing a current to flow between said first electrode and a second electrode, and detecting said current flow at said output wires.

22. A method of detecting radiation as claimed in claim 21, including the steps of measuring said current flow at said output wires and determining a dosage level of said radiation beam.

23. A method of constructing a detection device to detect radiation, said detection device having at least one carbon-based sensing element, said method comprising placing two electrodes on each of said at least one carbon-based sensing element, connecting said electrodes to a power source, connecting output wires to said carbon-based sensing elements, and arranging a current detector to detect current flowing in said output wires.

24. A method of constructing a detection device as claimed in claim 23, wherein said current detector is a control circuit, said method including the steps of measuring said current flow at said output wires and determining a dosage level of said radiation beam using said control circuit.

25. A detection device as claim in claim 1 wherein said radiation is Ultra-Violet (UV), proton, neutron, photon, electron or gamma beam.

26. A dosimeter for detecting radiation as claimed in claim 21, which is integrated into a garment.

27. A detection device as claimed in claim 1, which is an on-planar radiation sensor.
